(19) United States
(12) Patent Application Publication
(10) Pub. No.: US 2016/0216428 A1
(43) Pub. Date: Jul. 28, 2016

(54) POLARIZING PLATE, DISPLAY DEVICE INCLUDING THE SAME, AND METHOD OF MANUFACTURING THE SAME

(71) Applicant: SAMSUNG DISPLAY CO., LTD., Yongin-City (KR)

(72) Inventor: Hyunshik LEE, Incheon (KR)

(21) Appl. No.: 14/956,621

(22) Filed: Dec. 2, 2015

(30) Foreign Application Priority Data
Jan. 26, 2015 (KR) 10-2015-0012298

(51) Int. Cl. G02B 5/30; H01L 51/00; H01L 51/52; G02B 1/08

(52) U.S. Cl. CPC G02B 5/3083; G02B 5/305; G02B 1/08; H01L 51/0067; H01L 51/007; H01L 51/0059; H01L 51/006; H01L 51/0058; H01L 51/5293; H01L 2051/0063

(57) ABSTRACT

A display device includes a display panel that displays an image, a polarizing film on a surface of the display panel on which the image is displayed, and an optical compensation member between the display panel and the polarizing film, the optical compensation member including a substituted or non-substituted conjugated aromatic compound.

### CROSS-REFERENCE TO RELATED APPLICATION

Korean Patent Application No. 10-2015-0012298, filed on Jan. 26, 2015, in the Korean Intellectual Property Office, and entitled: “Polarizing Plate, Display Device Including the Same, and Method of Manufacturing the Same,” is incorporated by reference herein in its entirety.

### BACKGROUND

1. Field

Embodiments relate to a polarizing plate, a display device including the same, and a method of manufacturing the same.

2. Description of the Related Art

Flat display devices may be classified into two main groups: a light-emitting type and a light-receiving type. Examples of the light emitting type include a flat cathode ray tube, a plasma display panel, an organic light-emitting display (OLED), and the like. The organic light-emitting display is a self-luminous display device, and has advantages such as wide viewing angle, excellent contrast, and rapid response.

The organic light-emitting display may be applicable to a display device of mobile devices such as a digital camera, a video camera, a camcorder, a portable information terminal, a smartphone, an ultra-slim notebook, a tablet personal computer, and a flexible device, or a large-sized electronic/electric product such as an ultra-thin television.

The organic light-emitting display can provide a color according to a principle in which holes and electrons injected into an anode and a cathode, respectively, are re-combined in an organic light-emitting layer to emit light. Here, the injected holes and electrons are combined to generate excitons, and the excitons emit light when returned from an excitation state to a ground state.

### SUMMARY

Embodiments are directed to a display device including a display panel that displays an image, a polarizing film on a surface of the display panel on which the image is displayed, and an optical compensation member between the display panel and the polarizing film, the optical compensation member including a substituted or non-substituted conjugated aromatic compound.

The conjugated aromatic compound may be an arylamine derivative.

The arylamine derivative may include at least one selected from compounds represented by the following chemical formulas 1 to 7:

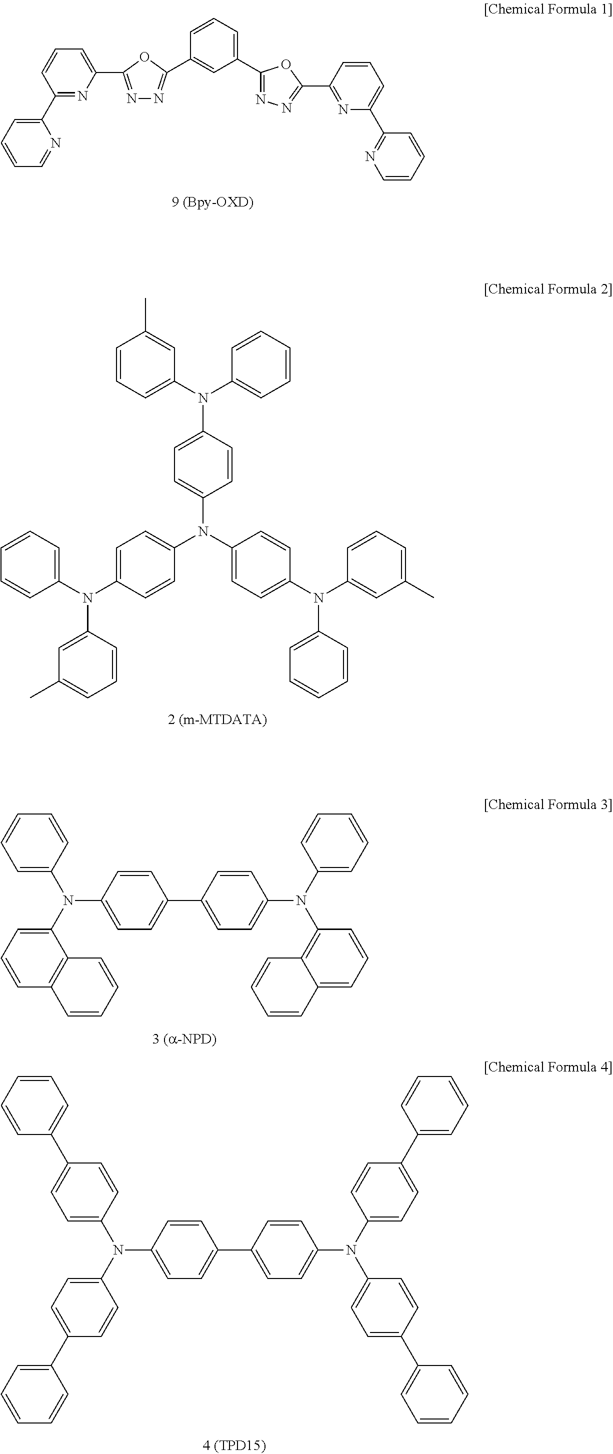 [SMILES: c1ccc(-c2cccc(-c3nnc(-c4cccc(-c5nnc(-c6cccc(-c7ccccn7)n6)o5)c4)o3)n2)nc1 ; Cc1cccc(N(c2ccccc2)c2ccc(N(c3ccc(N(c4ccccc4)c4cccc(C)c4)cc3)c3ccc(N(c4ccccc4)c4cccc(C)c4)cc3)cc2)c1 ; c1ccc(N(c2ccc(-c3ccc(N(c4ccccc4)c4cccc5ccccc45)cc3)cc2)c2cccc3ccccc23)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1]

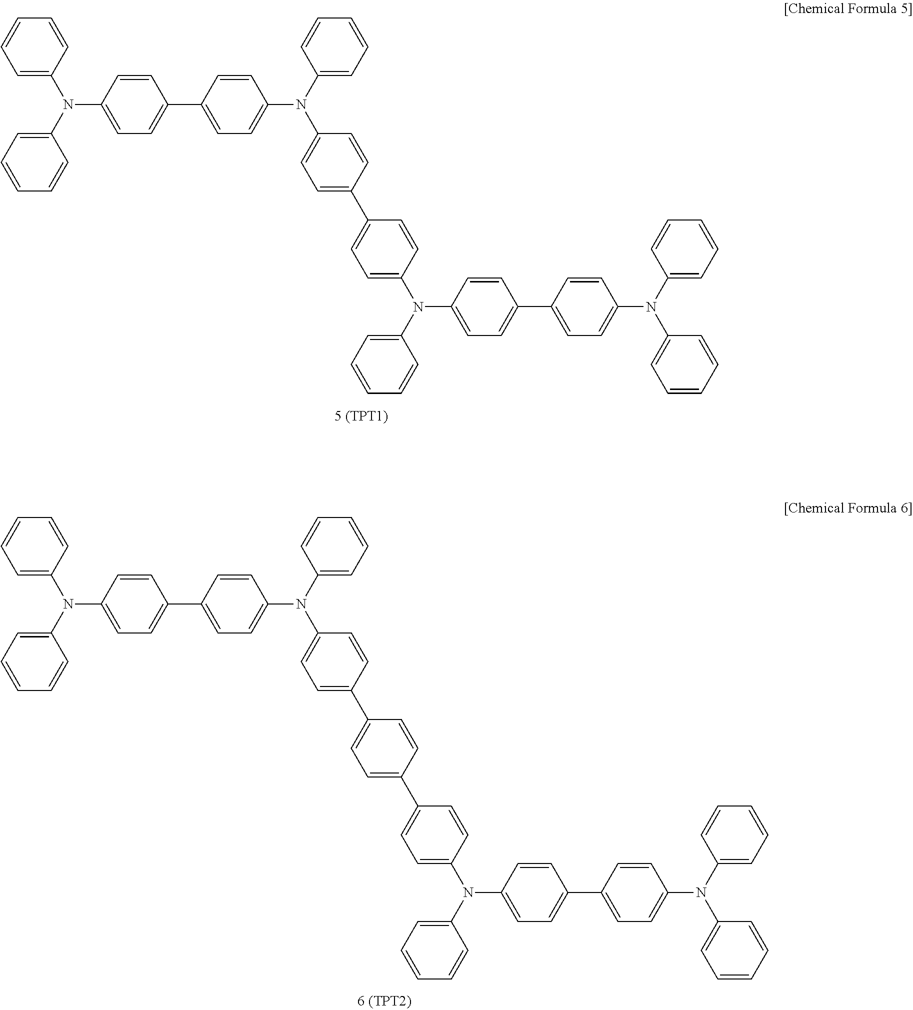 [SMILES: c1ccc(N(c2ccccc2)c2ccc(-c3ccc(N(c4ccccc4)c4ccc(-c5ccc(N(c6ccccc6)c6ccc(-c7ccc(N(c8ccccc8)c8ccccc8)cc7)cc6)cc5)cc4)cc3)cc2)cc1 ; c1ccc(N(c2ccccc2)c2ccc(-c3ccc(N(c4ccccc4)c4ccc(-c5ccc(-c6ccc(N(c7ccccc7)c7ccc(-c8ccc(N(c9ccccc9)c9ccccc9)cc8)cc7)cc6)cc5)cc4)cc3)cc2)cc1]

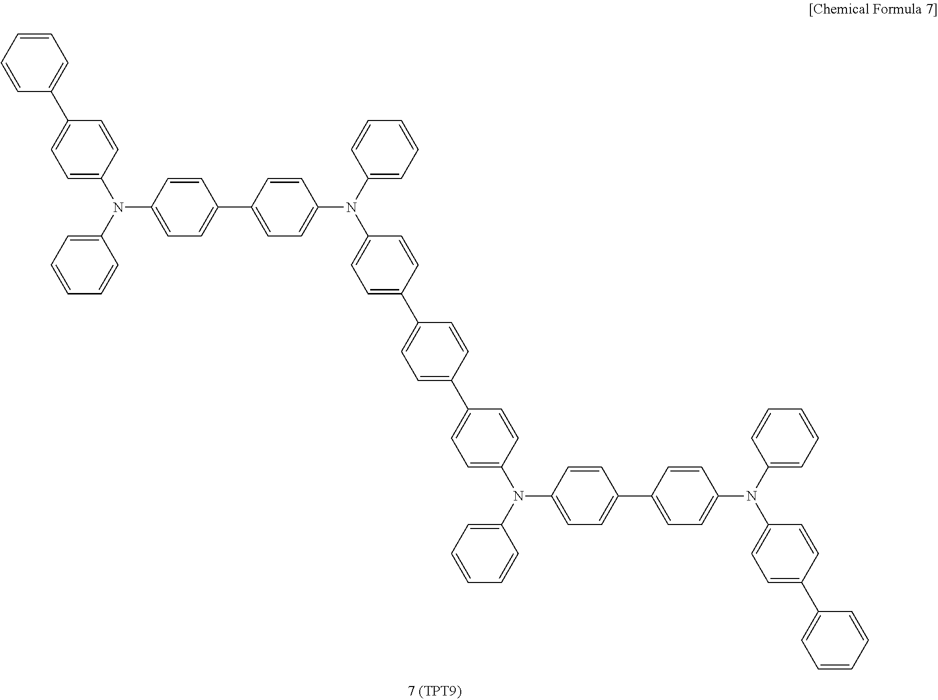 [SMILES: c1ccc(-c2ccc(N(c3ccccc3)c3ccc(-c4ccc(N(c5ccccc5)c5ccc(-c6ccc(-c7ccc(N(c8ccccc8)c8ccc(-c9ccc(N(c%10ccccc%10)c%10ccc(-c%11ccccc%11)cc%10)cc9)cc8)cc7)cc6)cc5)cc4)cc3)cc2)cc1]

The optical compensation member may be a C-plate.

The display device may further include a phase delay layer between the polarizing film and the optical compensation member.

The phase delay layer may include a ¼ wavelength plate.

The phase delay layer may further include a ½ wavelength plate.

Embodiments are also directed to a polarizing member including a polarizing layer that polarizes light in one direction, and an optical compensation layer on one surface of the polarizing layer, the optical compensation layer including a substituted or non-substituted conjugated aromatic compound.

The conjugated aromatic compound may be an arylamine derivative.

The arylamine derivative may include at least one selected from compounds represented by the following chemical formulas 1 to 7:

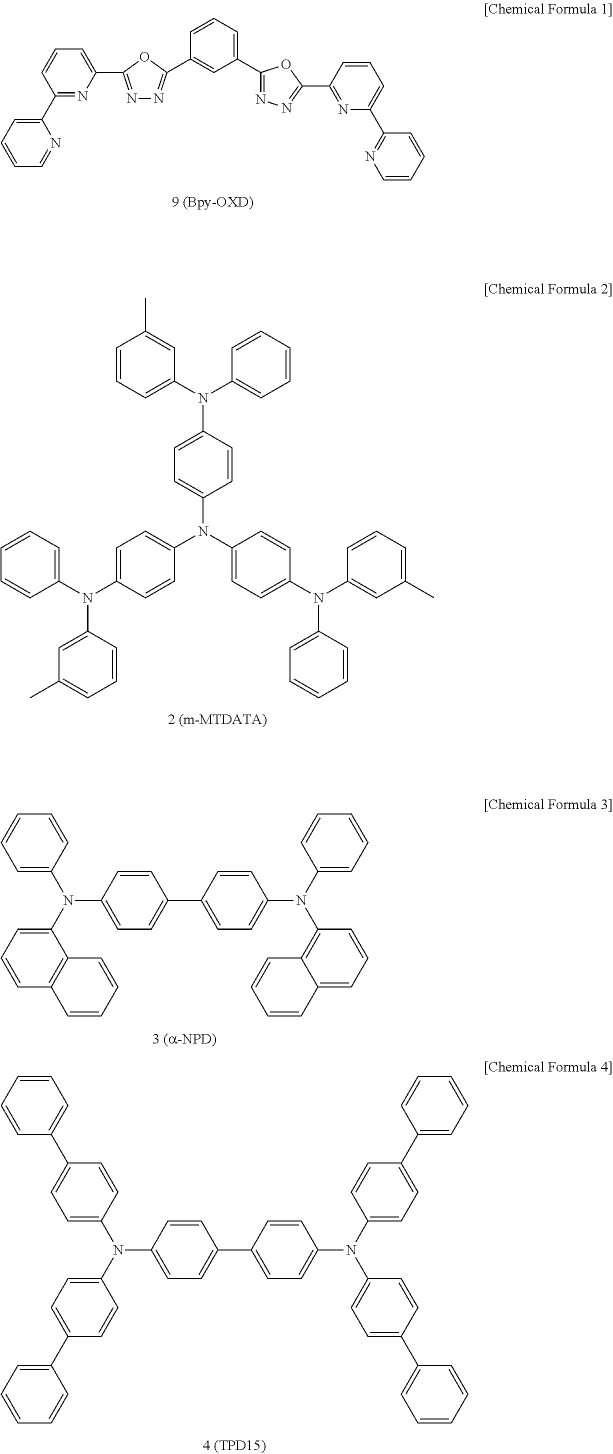 [SMILES: c1ccc(-c2cccc(-c3nnc(-c4cccc(-c5nnc(-c6cccc(-c7ccccn7)n6)o5)c4)o3)n2)nc1 ; Cc1cccc(N(c2ccccc2)c2ccc(N(c3ccc(N(c4ccccc4)c4cccc(C)c4)cc3)c3ccc(N(c4ccccc4)c4cccc(C)c4)cc3)cc2)c1 ; c1ccc(N(c2ccc(-c3ccc(N(c4ccccc4)c4cccc5ccccc45)cc3)cc2)c2cccc3ccccc23)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1]

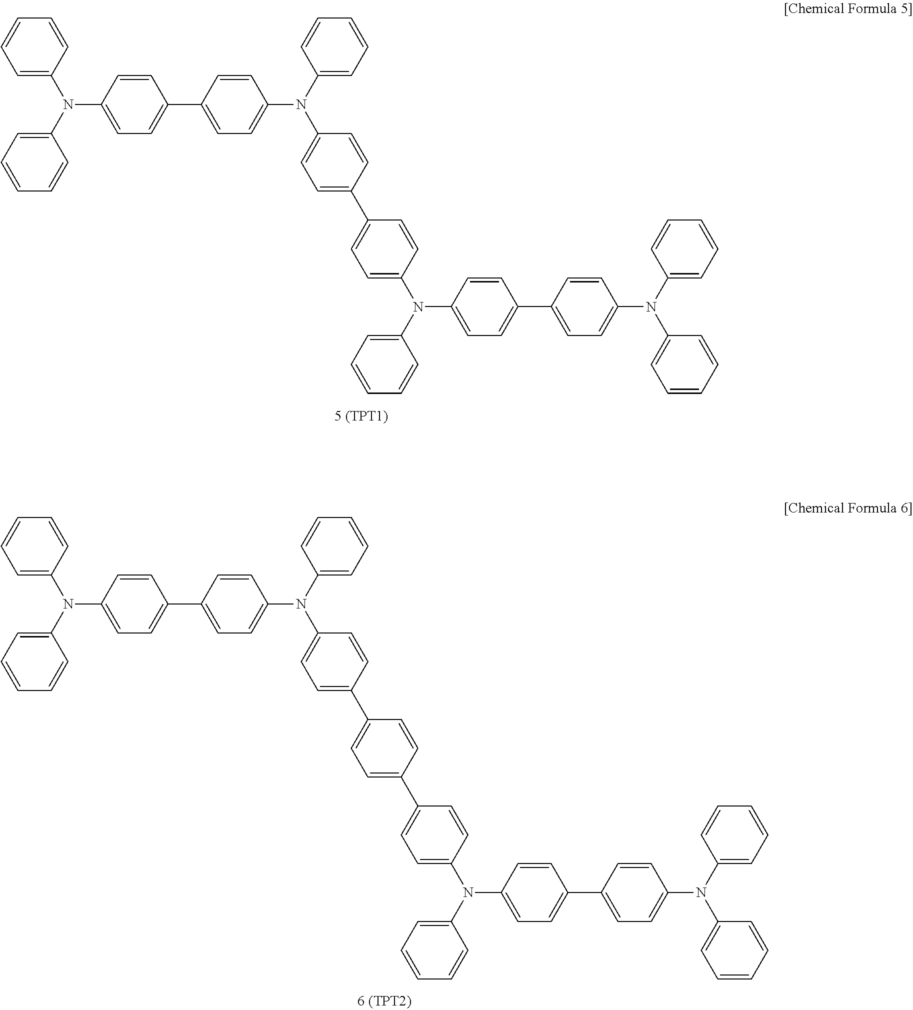 [SMILES: c1ccc(N(c2ccccc2)c2ccc(-c3ccc(N(c4ccccc4)c4ccc(-c5ccc(N(c6ccccc6)c6ccc(-c7ccc(N(c8ccccc8)c8ccccc8)cc7)cc6)cc5)cc4)cc3)cc2)cc1 ; c1ccc(N(c2ccccc2)c2ccc(-c3ccc(N(c4ccccc4)c4ccc(-c5ccc(-c6ccc(N(c7ccccc7)c7ccc(-c8ccc(N(c9ccccc9)c9ccccc9)cc8)cc7)cc6)cc5)cc4)cc3)cc2)cc1]

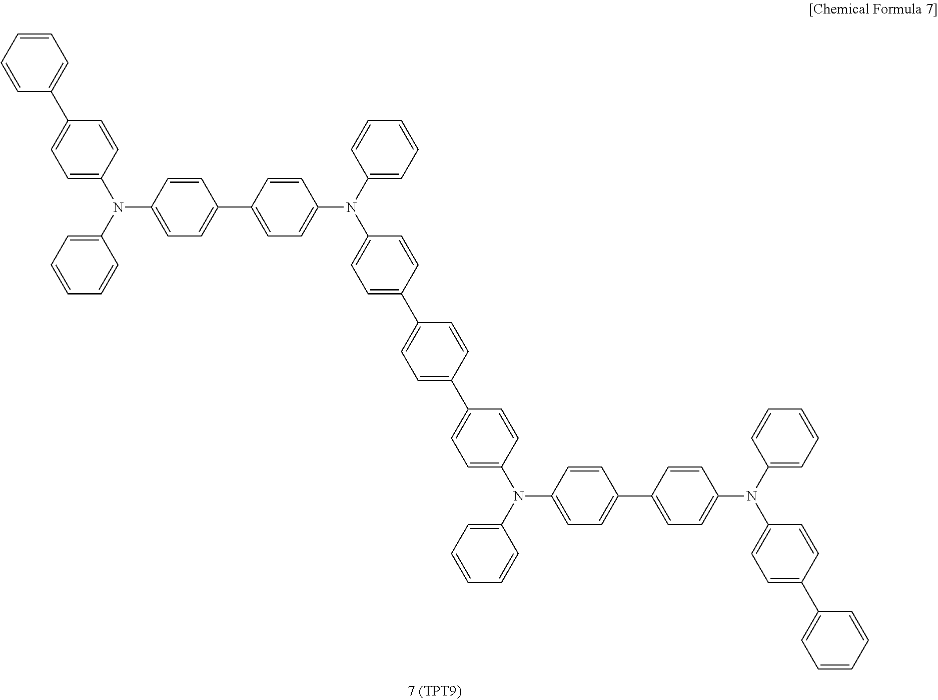 [SMILES: c1ccc(-c2ccc(N(c3ccccc3)c3ccc(-c4ccc(N(c5ccccc5)c5ccc(-c6ccc(-c7ccc(N(c8ccccc8)c8ccc(-c9ccc(N(c%10ccccc%10)c%10ccc(-c%11ccccc%11)cc%10)cc9)cc8)cc7)cc6)cc5)cc4)cc3)cc2)cc1]

The optical compensation layer may be a C-plate.

The polarizing plate may further include a phase delay layer provided between the polarizing layer and the optical compensation layer.

The phase delay layer may include a ¼ wavelength plate.

The phase delay layer may include a ½ wavelength plate.

Embodiments are also directed to a method of manufacturing a polarizing plate, including a polarizing film, and depositing a substituted or non-substituted conjugated aromatic compound on the polarizing film to form an optical compensation member.

The conjugated aromatic compound may be an arylamine derivative.

The arylamine derivative may include at least one selected from compounds represented by the following chemical formulas 1 to 7:

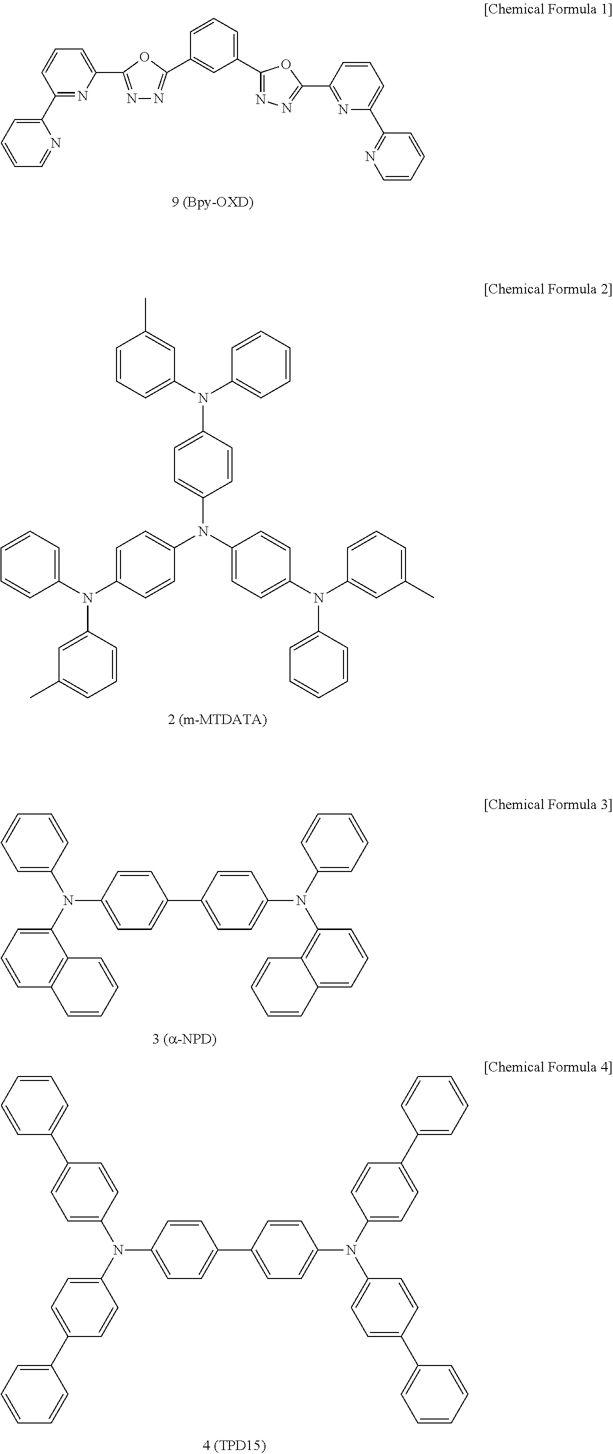 [SMILES: c1ccc(-c2cccc(-c3nnc(-c4cccc(-c5nnc(-c6cccc(-c7ccccn7)n6)o5)c4)o3)n2)nc1 ; Cc1cccc(N(c2ccccc2)c2ccc(N(c3ccc(N(c4ccccc4)c4cccc(C)c4)cc3)c3ccc(N(c4ccccc4)c4cccc(C)c4)cc3)cc2)c1 ; c1ccc(N(c2ccc(-c3ccc(N(c4ccccc4)c4cccc5ccccc45)cc3)cc2)c2cccc3ccccc23)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1]

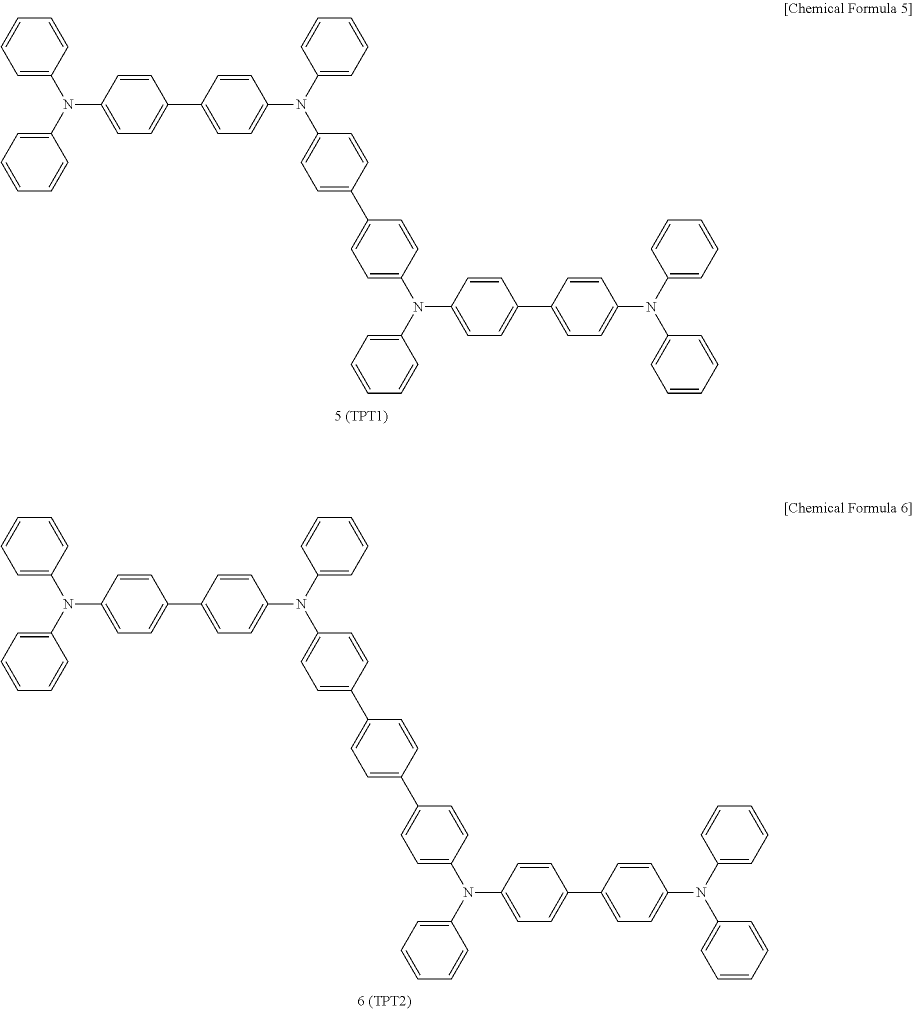 [SMILES: c1ccc(N(c2ccccc2)c2ccc(-c3ccc(N(c4ccccc4)c4ccc(-c5ccc(N(c6ccccc6)c6ccc(-c7ccc(N(c8ccccc8)c8ccccc8)cc7)cc6)cc5)cc4)cc3)cc2)cc1 ; c1ccc(N(c2ccccc2)c2ccc(-c3ccc(N(c4ccccc4)c4ccc(-c5ccc(-c6ccc(N(c7ccccc7)c7ccc(-c8ccc(N(c9ccccc9)c9ccccc9)cc8)cc7)cc6)cc5)cc4)cc3)cc2)cc1]

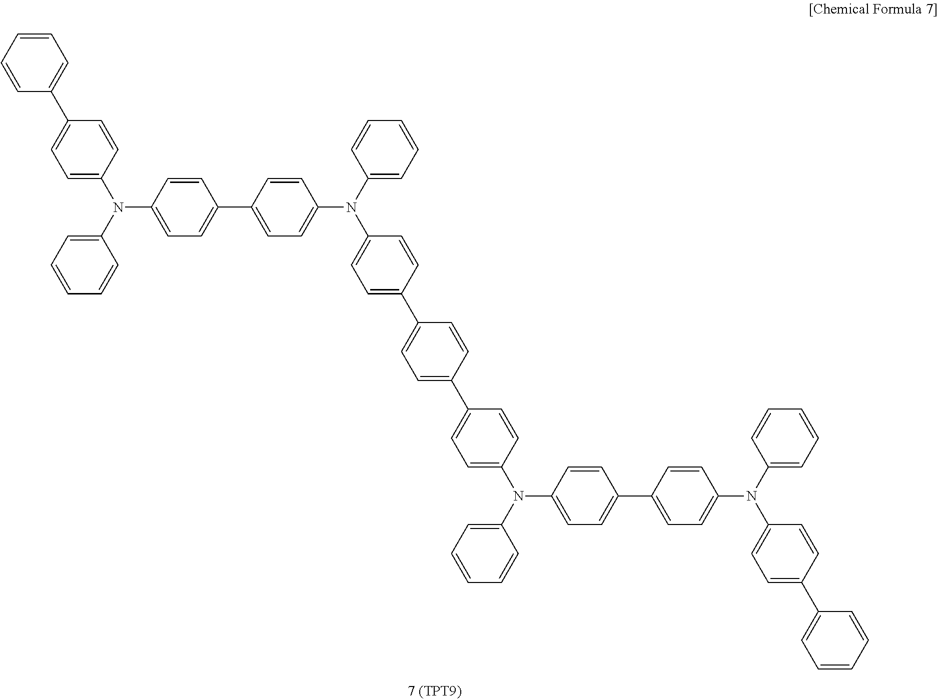 [SMILES: c1ccc(-c2ccc(N(c3ccccc3)c3ccc(-c4ccc(N(c5ccccc5)c5ccc(-c6ccc(-c7ccc(N(c8ccccc8)c8ccc(-c9ccc(N(c%10ccccc%10)c%10ccc(-c%11ccccc%11)cc%10)cc9)cc8)cc7)cc6)cc5)cc4)cc3)cc2)cc1]

The optical compensation member may be a C-plate.

### BRIEF DESCRIPTION OF THE DRAWINGS

Features will become apparent to those of skill in the art by describing in detail exemplary embodiments with reference to the attached drawings in which:

FIG. 1 illustrates a cross-sectional view depicting a display device according to an embodiment;

FIG. 2 illustrates a circuit diagram showing one pixel of a display panel in a display device according to an embodiment;

FIG. 3 illustrates a cross-sectional view depicting a display panel;

FIG. 4 illustrates a cross-sectional view depicting a polarizing plate according to an embodiment;

FIG. 5 illustrates a graph showing a refractive index of a deposited layer formed by depositing a non-conjugated aromatic compound as Comparative Example;

FIGS. 6A to 6G illustrate graphs showing a refractive index of a layer formed by depositing a conjugated aromatic compound of Chemical Formulas 1 through 7, respectively; and

FIGS. 7A and 7B illustrate graphs respectively showing luminous reflectance of a polarizing plate that does not include an optical compensation member as the Comparative Example, and a display device employing a polarizing plate that includes an optical compensation member as the Example.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “between” two layers, it can be the only layer between the two layers, or one or more intervening layers may also be present. Like reference numerals refer to like elements throughout.

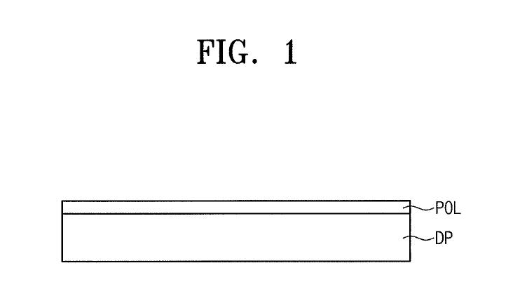

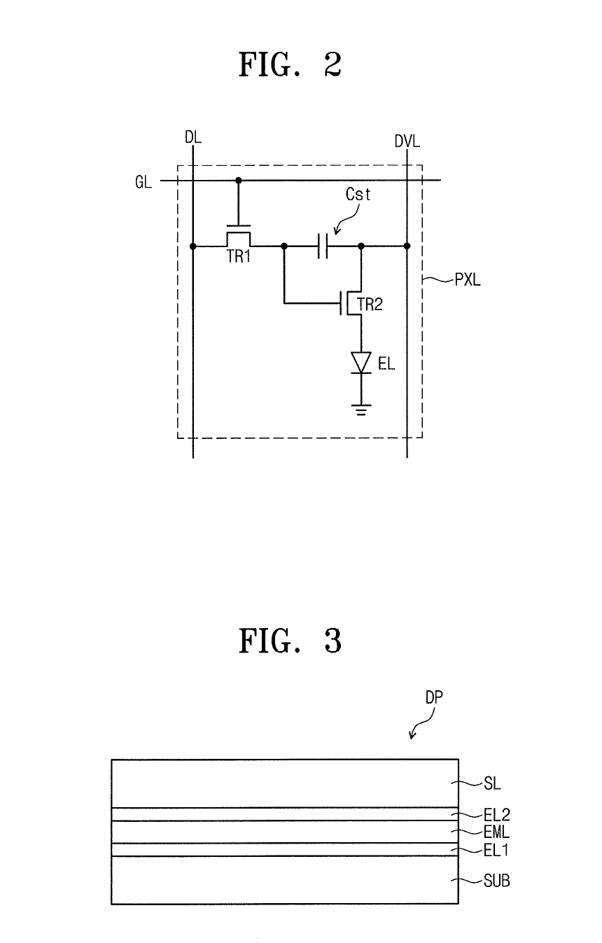

FIG. 1 illustrates a cross-sectional view depicting a display device according to an embodiment, and FIG. 2 illustrates a circuit diagram showing one pixel of a display panel in a display device according to an embodiment. FIG. 3 illustrates a cross-sectional view depicting a display panel, and illustrates stacking relations of some constituent elements.

Referring to FIGS. 1 and 3, a display device according to an embodiment may include a display panel DP displaying an image and a polarizing plate POL provided on the display panel DP.

The display panel DP may include a substrate SUB, a plurality of pixels PXL, and an encapsulating member SL.

The substrate SUB may be provided in the form of a rectangular plate having long sides and short sides. The pixels PXL may be provided on the substrate SUB in a matrix configuration. The substrate SUB may be made of a suitable material such as glass, silicon, a metal, or plastic.

The pixels PXL may be provided on the substrate SUB.

Each pixel PXL may include a wiring unit, a thin film transistor connected to the wiring unit, an organic light-emitting diode EL connected to the thin film transistor, and a capacitor Cst.

The wiring unit may include a gate line GL, a data line DL, and a driving voltage line DVL.

The gate line GL may extend in one direction. The data line DL may extend in another direction intersecting with the gate line GL. The driving voltage line DVL may extend in substantially the same direction as the data line DL. The gate line GL may transfer a scanning signal to the thin film transistor, the data line DL may transfer a data signal to the thin film transistor, and the driving voltage line DVL may supply a driving voltage to the thin film transistor.

The thin film transistor may include a driving thin film transistor TR2 that controls the organic light-emitting diode EL and a switching thin film transistor TR1 that switches the driving thin film transistor TR2. While it is described that one pixel PXL includes two transistors TR1 and TR2, in other embodiments, the number of transistors and capacitors may vary. For example, one pixel PXL may include one thin film transistor and one capacitor, or one pixel PXL may include at least three thin film transistors and at least two capacitors.

The switching thin film transistor TR1 may include a first gate electrode, a first source electrode, and a first drain electrode. The first gate electrode may be connected to the gate line GL, and the first source electrode may be connected to the data line DL. The first drain electrode may be connected to a gate electrode (that is, to a second gate electrode) of the driving thin film transistor TR2. The switching thin film transistor TR1 may transfer a data signal applied to the data line DL to the driving thin film transistor TR2 according to a scanning signal applied to the gate line GL.

The driving thin film transistor TR2 may include a second gate electrode, a second source electrode, and a second drain electrode. The second gate electrode may be connected to the switching thin film transistor TR1, the second source electrode may be connected to the driving voltage line DVL, and the second drain electrode may be connected to the organic light-emitting diode EL.

The organic light-emitting diode EL may include a light-emitting layer EML, and a first electrode EL1 and a second electrode EL2 opposed to each other with the light-emitting layer EML in-between. The first electrode EL1 may be connected to the second drain electrode of the driving thin film transistor TR2. Common voltage may be applied to the second electrode EL2. The light-emitting layer EML may emit light according to an output signal of the driving thin film transistor TR2 to display an image. The light emitted from the light-emitting layer EML may be white light, for example.

The capacitor Cst may be connected between the second gate electrode and second source electrode of the driving thin film transistor TR2. The capacitor Cst may charge and maintain a data signal inputted to the second gate electrode of the driving thin film transistor TR2.

Again referring to FIG. 3, the first electrode EL1 may be provided on the substrate SUB. The first electrode EL1 may be, for example, a cathode of the organic light-emitting diode EL. In addition, the light-emitting layer EML may be provided on the first electrode EL1. The second electrode EL2 may be provided on the light-emitting layer EML and may be, for example, an anode of the organic light-emitting diode EL. The wiring unit and the thin film transistor may be provided between the substrate SUB and the first electrode EL1.

Any one of the first electrode EL1 and the second electrode EL2 may be used as an anode, and the other one of the first electrode EL1 and the second electrode EL2 may be used as a cathode. In addition, the positional relation, the formation material, or the like of the anode and the cathode may be varied according to a displaying direction of an image.

The first electrode EL1 may include a material having a low work function, such as a metal, an alloy, a conductive compound, or a mixture thereof. For example, the material of the first electrode EL1 may include lithium (Li), magnesium (Mg), aluminum (Al), aluminum-lithium (Al—Li), calcium (Ca), magnesium-indium (Mg—In), magnesium-silver (Mg—Ag), or the like.

In an implementation, the light-emitting layer EML may emit white light. The light-emitting layer EML may be formed by using a suitable light-emitting material, such as a light-emitting material including a host material and a dopant material. A fluorescent dopant material and a phosphorescent dopant material may be used as the dopant material. For example, the host material may include Alq3, 4,4-N,N-dicarbazole-biphenyl (CBP), 9,10-di(naphthalen-2-yl)anthracene (AND), or distyrylarylene (DSA). In another implementations, the light-emitting layer may emit color light.

The second electrode EL2 may be formed of a material having a high work function. When it is intended to provide an image in an upper direction of the substrate SUB in FIG. 3, the second electrode EL2 may be formed of a transparent conductive film such as indium tin oxide (ITO), indium zinc oxide (IZO), zinc oxide (ZnO), or indium tin zinc oxide (ITZO).

The light-emitting layer EML may be in a form of a single layer. In some implementations, the light-emitting layer EML may be in a form of a multi-layer. For example, the light-emitting layer EML may include an electron injection layer and an electron transport layer sequentially adjacent to the first electrode EL1, and may include a hole injection layer and a hole transport layer sequentially adjacent to the second electrode EL2.

An encapsulating member SL may be provided on the second electrode EL2 to encapsulate the pixels PXL.

The polarizing plate POL may be provided on one surface of the display panel on which the image is displayed. The polarizing plate POL may be attached to the display panel DP by an adhesive applied therebetween. In an embodiment, the polarizing plate POL may be provided on the encapsulating member SL.

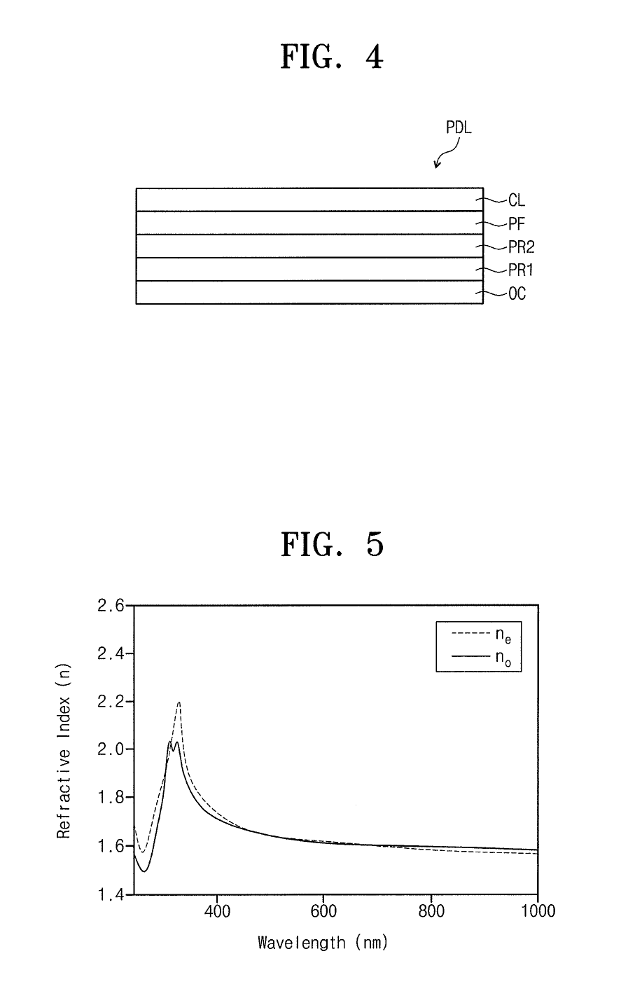

FIG. 4 illustrates a cross-sectional view depicting a polarizing plate according to an embodiment.

Referring to FIG. 4, the polarizing plate POL according to an embodiment may include a polarizing film PF and an optical compensation member OC provided on one side of the polarizing film PF.

The polarizing film PF may be an optical member that transmits a portion of light incident into the polarizing film PF to convert the incident light into polarized light.

The polarizing film PF may be made of a polymer resin oriented in a specific direction. The polymer resin may be a polyvinyl alcohol resin. The polyvinyl alcohol resin is obtained by saponifying a polyvinyl acetate resin. The polyvinyl acetate resin may include a homopolymer of vinyl acetate or a copolymer obtained by copolymerizing the vinyl acetate and a monomer that is copolymerizable with the vinyl acetate. Examples of the monomer copolymerizable with the vinyl acetate include an unsaturated carboxylic acid, olefin, vinyl ether, and an unsaturated sulfonic acid.

The optical compensation member OC may be an optical member for optically compensating for the phase of light traveling inside the polarizing film PF.

In an embodiment, the optical compensation member OC may be a material having a refractive anisotropy, for example, a C-plate. The C-plate meets the condition nₓ=n_{y}≠n_{z} wherein, among refractive indexes orthogonal to one another, a refractive index of an X-axis direction is referred to as nₓ, a refractive index of a Y-axis direction is referred to as n_{y}, and a refractive index of a thickness direction is referred to as n_{z}. When the optical compensation member OC is provided as the C-plate, a horizontal refractive index and a vertical refractive index of the optical compensation member OC are different from each other. Accordingly, when the optical compensation member OC is applied to a display panel, the optical compensation member OC may compensate for optical light paths of light beams traveling toward a front surface and a side surface of the display panel.

The optical compensation member OC may include a layer including a substituted or non-substituted conjugated aromatic compound. The layer including the conjugated aromatic compound may be formed through a deposition process, and accordingly, will be referred to as a conjugated aromatic compound-deposited layer.

Hereinafter, examples of the conjugated aromatic compound according to an embodiment will be described.

The conjugated aromatic compound according to an embodiment may have a molecular structure that is a plate shape, such that most of the atoms composing each molecule are disposed on the same plane. The conjugated aromatic compound may include instances where some of terminal groups are substituted with a non-conjugated functional group. The conjugated aromatic compound may include instances where a molecular structure is entirely in a same plane to have a substantially plate shape and thus may entirely have a conjugated aromatic moiety.

When the conjugated aromatic compound is formed through a deposition process, the plate-shaped molecules may overlap each other. Accordingly, a refractive index in a direction orthogonal to the plane may be different from a refractive index in a direction parallel to the plane. Among the conjugated aromatic compounds, a compound having a structure in which molecules are aligned by a polarity therein (for example, a structure in which molecules are able to form a hydrogen bond on a plane) may be disposed in a direction parallel to the plane by a deposition process. When the plane is defined as an X-Y plane consisting of an X-axis and a Y-axis, and a direction orthogonal to the X-Y plane is defined as a Z-axis, compounds may be sequentially stacked in the direction parallel to the X-Y plane. Accordingly, the density of a deposited layer in an X-Y plane direction may be different from a density in a Z-axis direction, and a refractive index in the X-axis direction and/or the Y-axis direction may be also different from a refractive index in the Z-axis direction. The optical compensation member OC formed by overlapping the conjugated aromatic compounds may have a refractive index anisotropy in a specific direction, for example, in the Z-axis direction. Accordingly, the optical compensation member OC may function as a C-plate.

In an embodiment, the conjugated aromatic compound may be an arylamine derivative. For example, the conjugated aromatic compound may include at least one selected from compounds represented by the following chemical formulas 1 to 7.

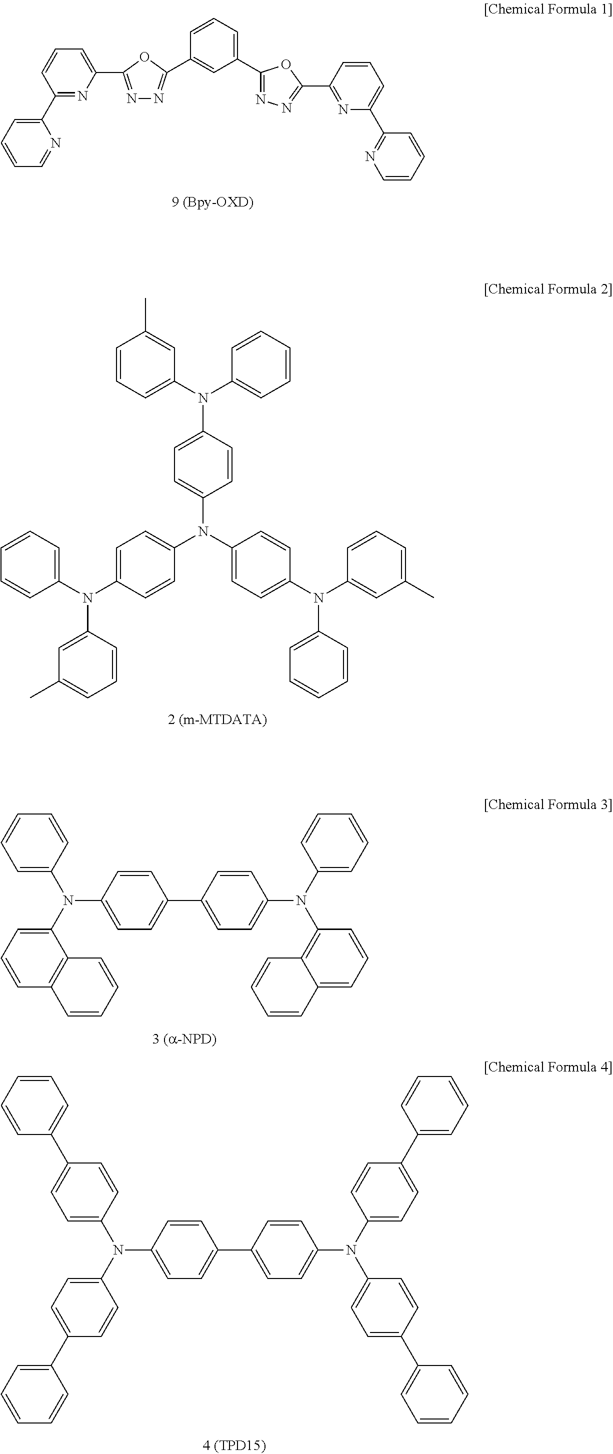 [SMILES: c1ccc(-c2cccc(-c3nnc(-c4cccc(-c5nnc(-c6cccc(-c7ccccn7)n6)o5)c4)o3)n2)nc1 ; Cc1cccc(N(c2ccccc2)c2ccc(N(c3ccc(N(c4ccccc4)c4cccc(C)c4)cc3)c3ccc(N(c4ccccc4)c4cccc(C)c4)cc3)cc2)c1 ; c1ccc(N(c2ccc(-c3ccc(N(c4ccccc4)c4cccc5ccccc45)cc3)cc2)c2cccc3ccccc23)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1]

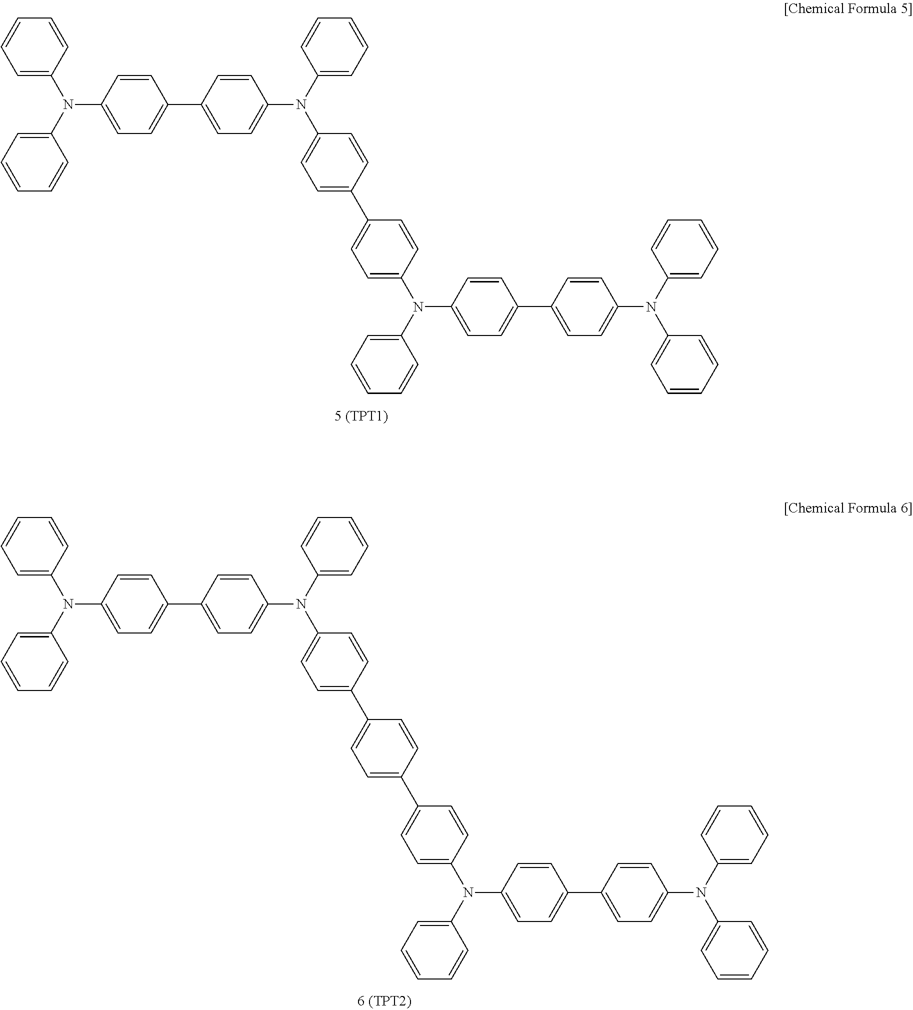 [SMILES: c1ccc(N(c2ccccc2)c2ccc(-c3ccc(N(c4ccccc4)c4ccc(-c5ccc(N(c6ccccc6)c6ccc(-c7ccc(N(c8ccccc8)c8ccccc8)cc7)cc6)cc5)cc4)cc3)cc2)cc1 ; c1ccc(N(c2ccccc2)c2ccc(-c3ccc(N(c4ccccc4)c4ccc(-c5ccc(-c6ccc(N(c7ccccc7)c7ccc(-c8ccc(N(c9ccccc9)c9ccccc9)cc8)cc7)cc6)cc5)cc4)cc3)cc2)cc1]

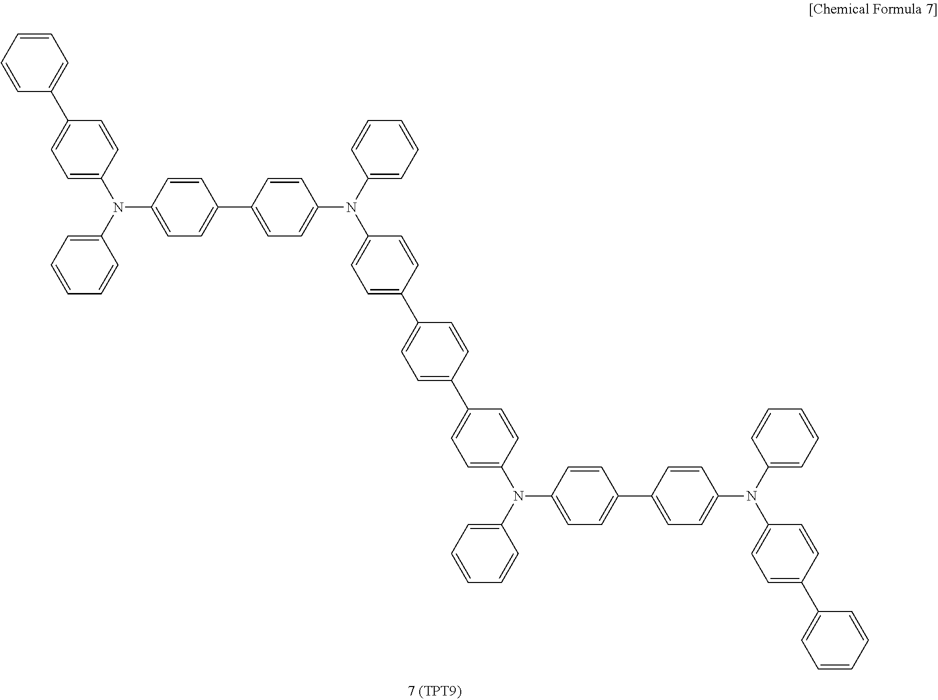 [SMILES: c1ccc(-c2ccc(N(c3ccccc3)c3ccc(-c4ccc(N(c5ccccc5)c5ccc(-c6ccc(-c7ccc(N(c8ccccc8)c8ccc(-c9ccc(N(c%10ccccc%10)c%10ccc(-c%11ccccc%11)cc%10)cc9)cc8)cc7)cc6)cc5)cc4)cc3)cc2)cc1]

A suitable conjugated aromatic compound that has an entire molecular structure with planarity and that has refractive index anisotropy through deposition may be used herein as the conjugated aromatic compound.

A phase delay layer may be additionally provided between the polarizing film PF and the optical compensation member OC.

The phase delay layer may be a layer that delays a phase of light travelling from the optical compensation member OC to the polarizing film PF. The phase delay layer may include at least one selected from a ¼ wavelength plate and a ½ wavelength plate. In an embodiment, the phase delay layer may include a first phase delay layer PR1 that is a ¼ wavelength plate and a second phase delay layer PR2 that is a ½ wavelength plate, and may suppress a reflection of outer light.

The phase delay layer may be made of a thermoplastic resin. Examples of the thermoplastic resin include polysulfone, polymethyl methacrylate, polystyrene, polycarbonate, polyvinyl chloride, and norbornene. The thermoplastic resin may be used alone, or may be used in mixture with each other.

A cover layer CL may be provided on the polarizing film PF. The cover layer CL may protect the polarizing film PF from outer scratches or the like.

In an embodiment, an adhesive may be provided between the first phase delay layer PR1 and the second phase delay layer PR2, and between the second phase delay layer PR2 and the polarizing film PF. The respective constituent elements may contact each other with the adhesive in-between. The polarizing plate having the aforementioned structure may be manufactured by providing the polarizing film PF, and forming the optical compensation member OC on the polarizing film PF. The optical compensation member OC may be formed by depositing a substituted or non-substituted conjugated aromatic compound.

In an embodiment, when the phase delay layer is further formed between the polarizing film PF and the optical compensation member OC, the optical compensation member OC may be formed by depositing the substituted or non-substituted conjugated aromatic compound on the phase delay layer A depositing condition in the deposition process may be selected according to the type of compound, and the depositing condition may be optimized through an experiment in order to obtain a desired refractive index anisotropy.

FIG. 5 is a graph showing a refractive index of a deposited layer formed by depositing a non-conjugated aromatic compound as Comparative Example. A compound represented by the following Chemical Formula 8 is used as a non-conjugated aromatic compound in FIG. 5.

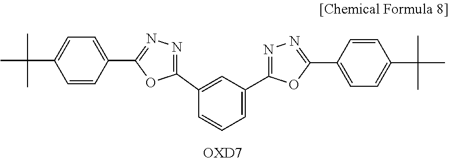 [SMILES: CC(C)(C)c1ccc(-c2nnc(-c3cccc(-c4nnc(-c5ccc(C(C)(C)C)cc5)o4)c3)o2)cc1]

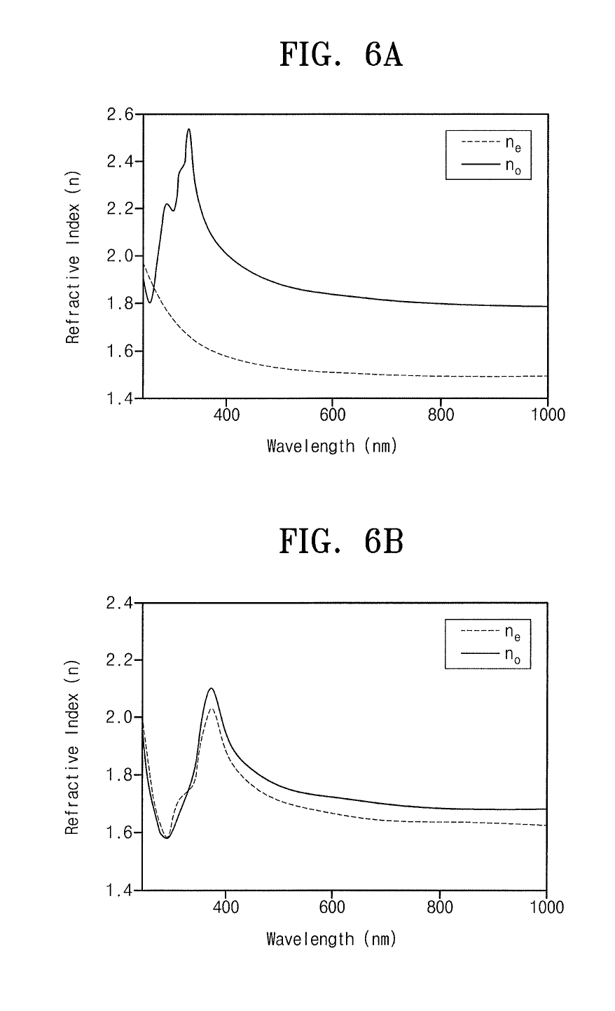

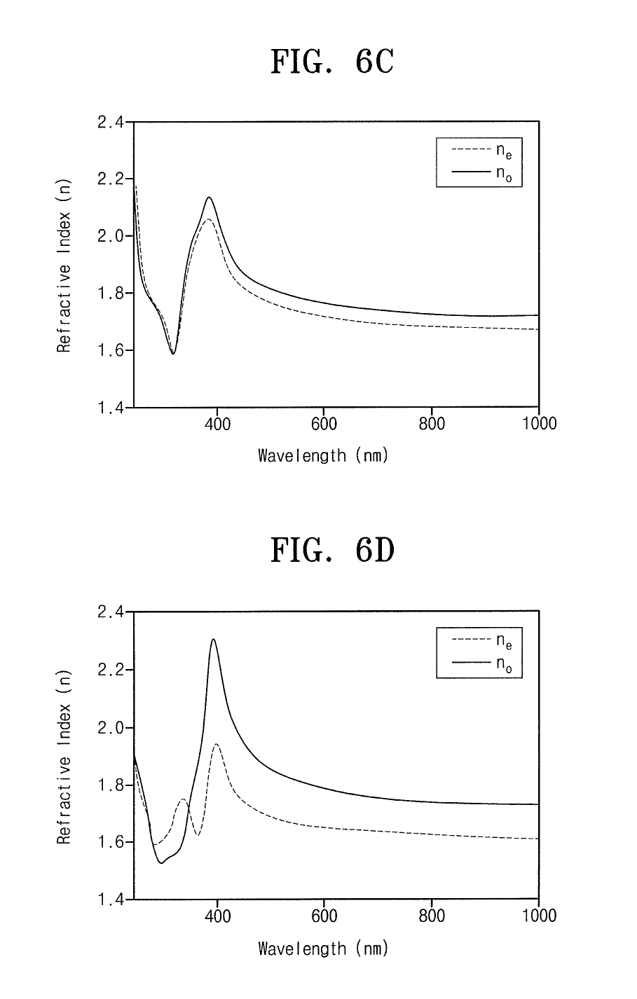

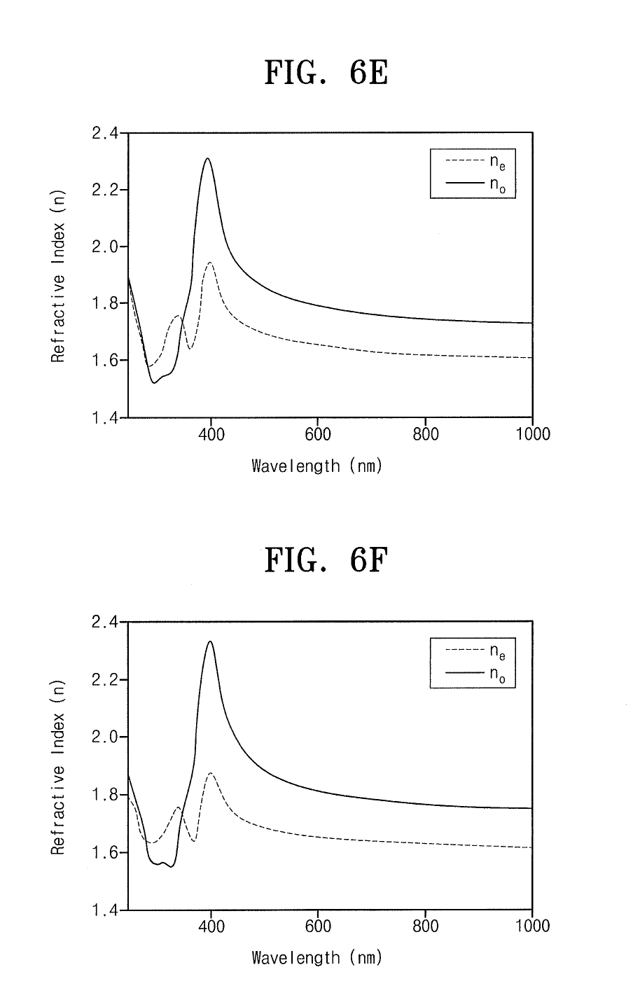

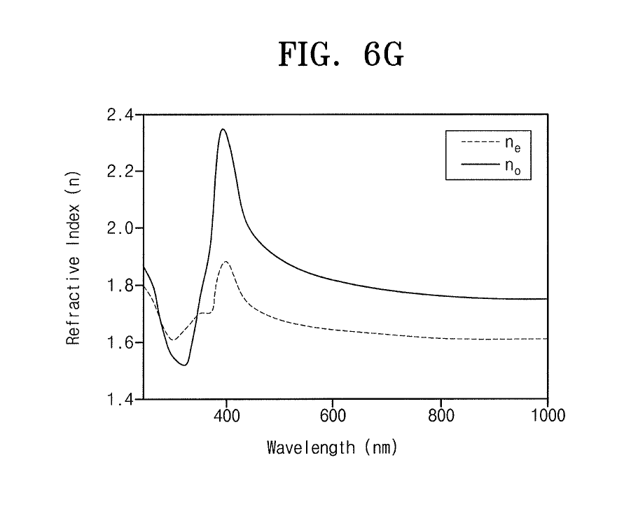

FIGS. 6A to 6G are graphs showing a refractive index of a layer formed by depositing a conjugated aromatic compound as Embodiments. In FIGS. 5 and 6A to 6G, nₒ is a refractive index in a direction orthogonal to an optical axis, and nₑ is a refractive index in a direction parallel to the optical axis. In FIGS. 6A to 6G, compounds represented by the aforementioned Chemical Formulas 1 to 7 are respectively used as conjugated aromatic compounds. That is, in FIG. 6A, the conjugated aromatic compound was the compound represented by Chemical Formula 1; in FIG. 6B, the conjugated aromatic compound was the compound represented by Chemical Formula 2, etc.

Referring to FIG. 5, in a deposited layer including the compound represented by Chemical Formula 8, the refractive index in the direction orthogonal to the optical axis is substantially equal to the refractive index in the direction parallel to the optical axis at most wavelengths of a visible light region. This result is believed to be due to the presence of t-butyl groups attached to both terminals of the compound represented by Chemical Formula 8, resulting in a structure in which atoms constituting the molecule are not disposed in the same plane. It is believed that in the case of the compound represented by Chemical Formula 8, a dense stacking is not formed in a specific direction in depositing and, as a result, the deposited layer has isotropy.

Referring to FIGS. 6A to 6G, in the deposited layers including compounds represented by Chemical Formulas 1 to 7, the refractive index in the direction orthogonal to the optical axis is different from that in the direction parallel to the optical at most wavelengths of a visible light region. It is believed that in the case of the compounds represented by Chemical Formulas 1 to 7, atoms constituting the molecule are substantially disposed in the same plane, and a dense stacking may be formed in a specific direction in depositing. As a result, it may be confirmed that the deposited layer has anisotropy.

According to an embodiment, a side viewing angle characteristic may be improved by providing an optical compensation member in addition to a polarizing film. The optical compensation member may be formed through a deposition process, accordingly, the polarizing plate may be thinner than a polarizing plate formed through an existing method. Manufacturing processes are simplified, and manufacturing costs may be reduced. Generally, an existing optical compensation member was manufactured by using a liquid crystal (for example, a discotic liquid crystal), and by applying the liquid crystal onto a substrate, aligning the liquid crystal, and then forming a passivation film protecting the liquid crystal. In this case, processes were complex, costs were considerably increased, and the resulting optical compensation member was relatively thick.

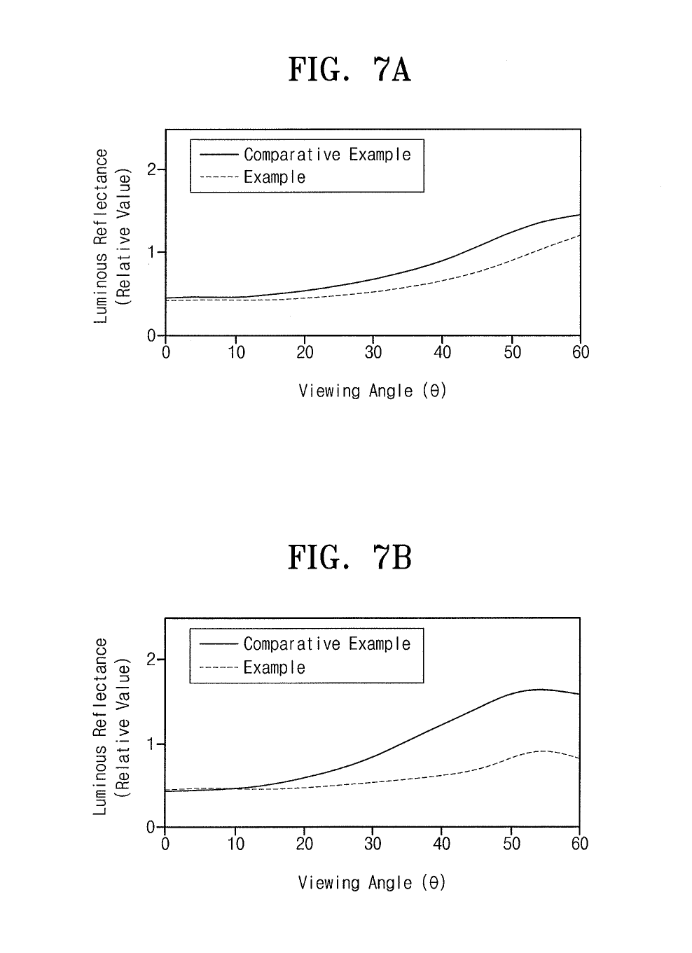

FIGS. 7A and 7B each respectively show luminous reflectance according to a viewing angle of a polarizing plate that does not include an optical compensation member as Comparative Example, and luminous reflectance according to a viewing angle of a display device employing a polarizing plate that includes the optical compensation member as Example. In FIGS. 7A and 7B, the optical compensation member of the Example includes the conjugated aromatic compound represented by Chemical Formula 1. The luminous reflectance values shown in FIG. 7A were measured according a viewing angle at one side, and the luminous reflectance values shown in FIG. 7B were measured according to the viewing angle at an opposite side of the one side. The polarizing plates used in FIGS. 7A and 7B had the same structure except for the existence or non-existence of the optical compensation member. In the Comparative Example, a phase delay layer, a polarizing film, and a cover layer were sequentially stacked. In the Example, an optical compensation member, a polarizing film. and a cover layer were sequentially stacked.

Referring to FIG. 7A, a display device employing a polarizing plate including an optical compensation member according to the Example showed an effect that when a viewing angle was about 60 degrees, luminous reflectance was about 12% less than that of Comparative Example. Referring to FIG. 7B, the display device employing the polarizing plate including the optical compensation member according to the Example showed an effect that when a viewing angle was about 60 degrees, luminous reflectance was about 47% less than that of the Comparative Example.

According to an embodiment, a polarizing plate may include an optical compensation member in addition to a polarizing film. Accordingly, the polarizing plate may have an improved side viewing angle characteristic when applied in a display device. In the polarizing plate. The optical compensation member is formed through a deposition process. Accordingly, the polarizing plate may be thinner than a polarizing plate formed through an existing method. Manufacturing processes may be simplified and manufacturing costs may be reduced.

By way of summation and review, in an organic light-emitting display, interference between light emitted from the organic light-emitting layer and outer natural light (outer light) that comes from the outside and is reflected on an inner reflection plate may occur to deteriorate display quality. In order to suppress the interference, the organic light-emitting display may include a polarizing plate. The polarizing plate may include a compensation film for improving a side viewing angle characteristic. However, a compensation film is generally manufactured by applying a liquid crystal. Accordingly, the manufacturing process thereof may be complex and expensive.

Embodiments provide a polarizing plate having improved side viewing angle characteristic. Embodiments also provide a method of manufacturing a polarizing plate simply at a low manufacturing cost. Embodiments also provide a display device having an improved side viewing angle characteristic. Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope thereof as set forth in the following claims.

What is claimed is:

1. A display device, comprising:
a display panel that displays an image;
a polarizing film on a surface of the display panel on which the image is displayed; and
an optical compensation member between the display panel and the polarizing film, the optical compensation member including a substituted or non-substituted conjugated aromatic compound.

2. The display device as claimed in claim 1, wherein the conjugated aromatic compound is an arylamine derivative.

3. The display device as claimed in claim 2, wherein the arylamine derivative includes at least one selected from compounds represented by the following chemical formulas 1 to 7:

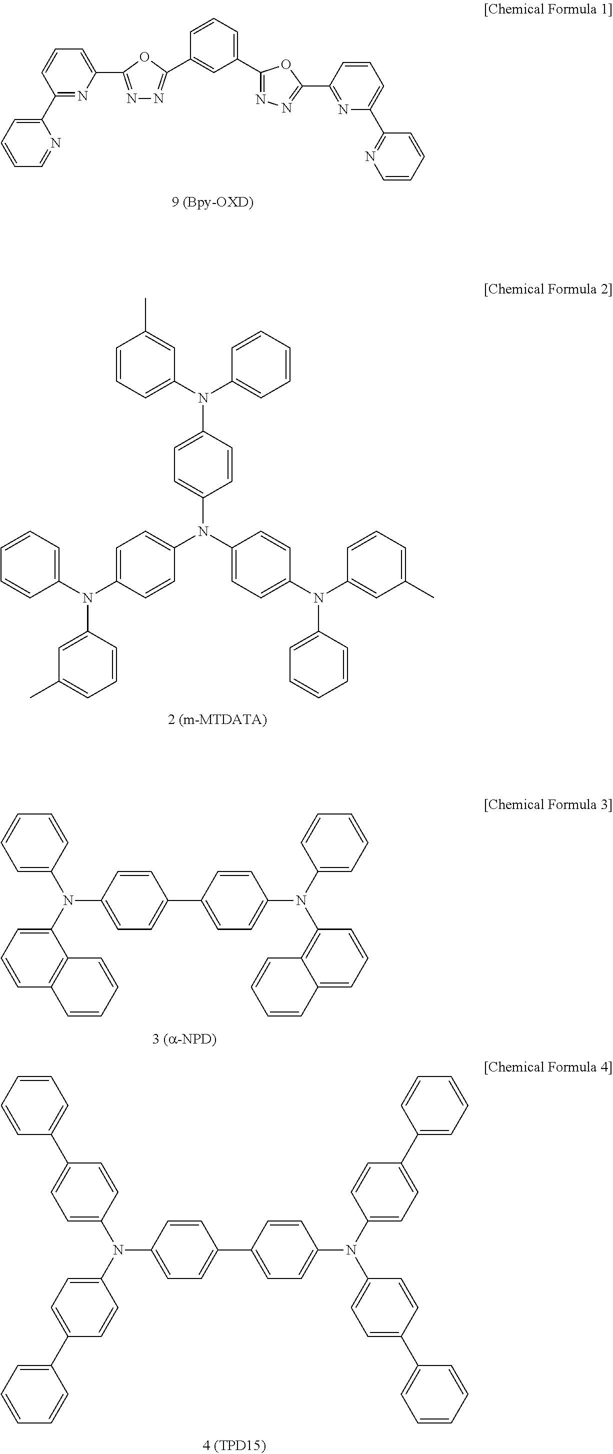 [SMILES: c1ccc(-c2cccc(-c3nnc(-c4cccc(-c5nnc(-c6cccc(-c7ccccn7)n6)o5)c4)o3)n2)nc1 ; Cc1cccc(N(c2ccccc2)c2ccc(N(c3ccc(N(c4ccccc4)c4cccc(C)c4)cc3)c3ccc(N(c4ccccc4)c4cccc(C)c4)cc3)cc2)c1 ; c1ccc(N(c2ccc(-c3ccc(N(c4ccccc4)c4cccc5ccccc45)cc3)cc2)c2cccc3ccccc23)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1]

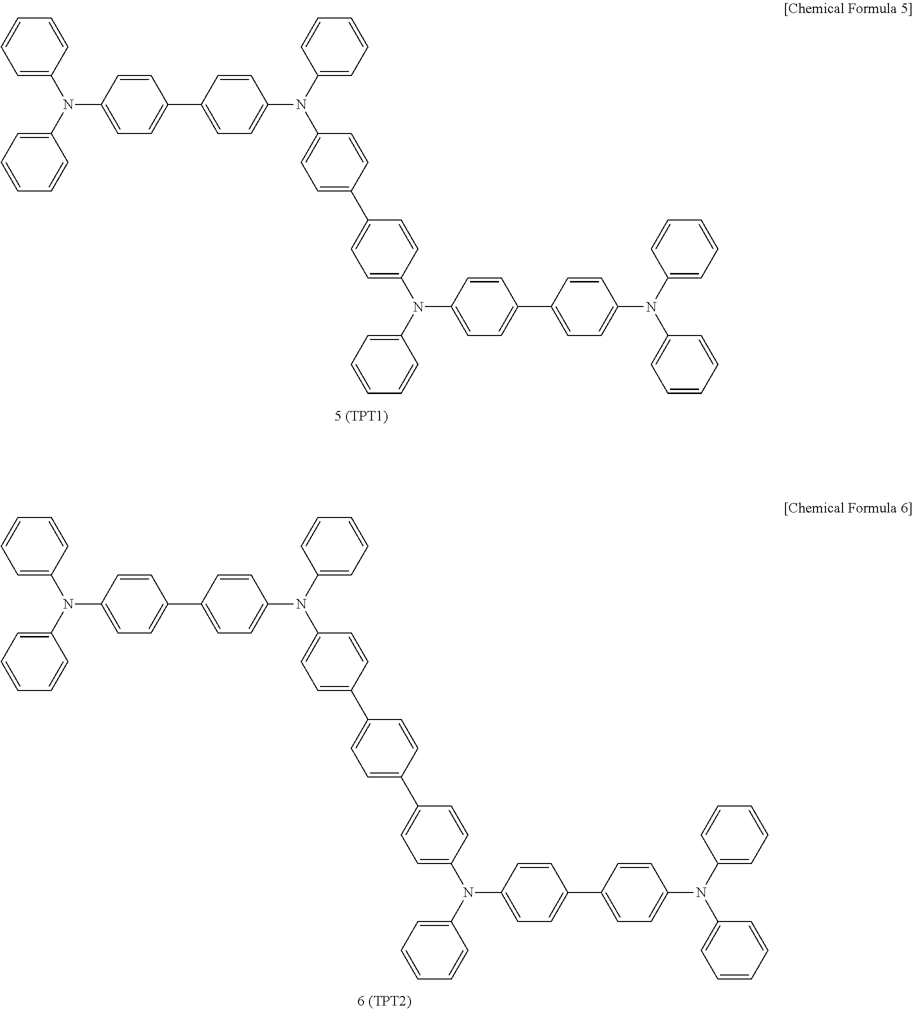 [SMILES: c1ccc(N(c2ccccc2)c2ccc(-c3ccc(N(c4ccccc4)c4ccc(-c5ccc(N(c6ccccc6)c6ccc(-c7ccc(N(c8ccccc8)c8ccccc8)cc7)cc6)cc5)cc4)cc3)cc2)cc1 ; c1ccc(N(c2ccccc2)c2ccc(-c3ccc(N(c4ccccc4)c4ccc(-c5ccc(-c6ccc(N(c7ccccc7)c7ccc(-c8ccc(N(c9ccccc9)c9ccccc9)cc8)cc7)cc6)cc5)cc4)cc3)cc2)cc1]

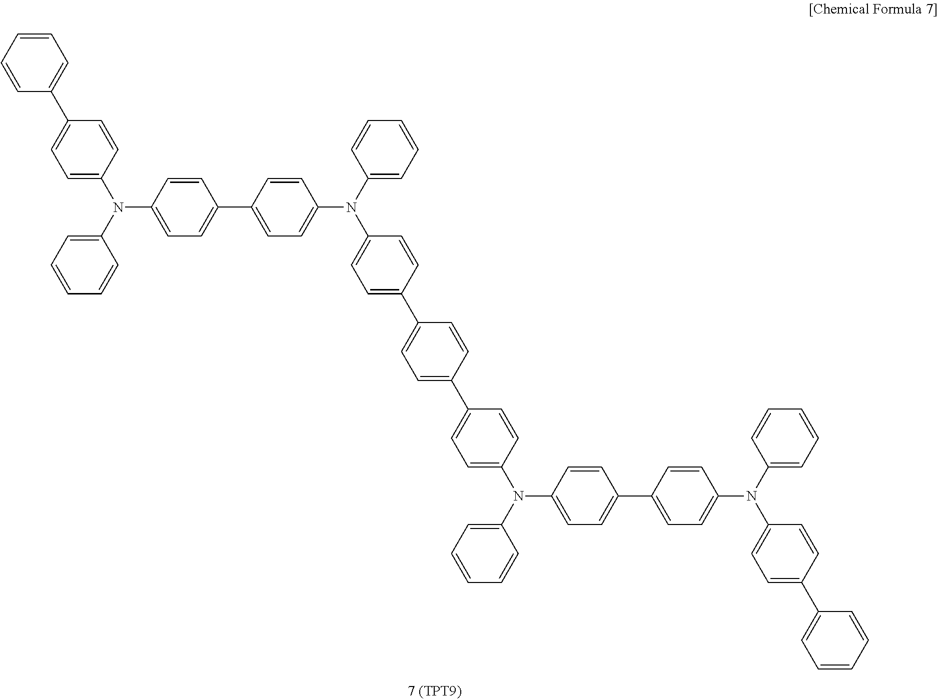 [SMILES: c1ccc(-c2ccc(N(c3ccccc3)c3ccc(-c4ccc(N(c5ccccc5)c5ccc(-c6ccc(-c7ccc(N(c8ccccc8)c8ccc(-c9ccc(N(c%10ccccc%10)c%10ccc(-c%11ccccc%11)cc%10)cc9)cc8)cc7)cc6)cc5)cc4)cc3)cc2)cc1]

4. The display device as claimed in claim 1, wherein the optical compensation member is a C-plate.

5. The display device as claimed in claim 1, further comprising a phase delay layer between the polarizing film and the optical compensation member.

6. The display device as claimed in claim 5, wherein the phase delay layer includes a ¼ wavelength plate.

7. The display device as claimed in claim 6, wherein the phase delay layer further includes a ½ wavelength plate.

8. A polarizing member, comprising:
a polarizing layer that polarizes light in one direction; and
an optical compensation layer on one surface of the polarizing layer, the optical compensation layer including a substituted or non-substituted conjugated aromatic compound.

9. The polarizing plate as claimed in claim 8, wherein the conjugated aromatic compound is an arylamine derivative.

10. The polarizing plate as claimed in claim 9, wherein the arylamine derivative includes at least one selected from compounds represented by the following chemical formulas 1 to 7:

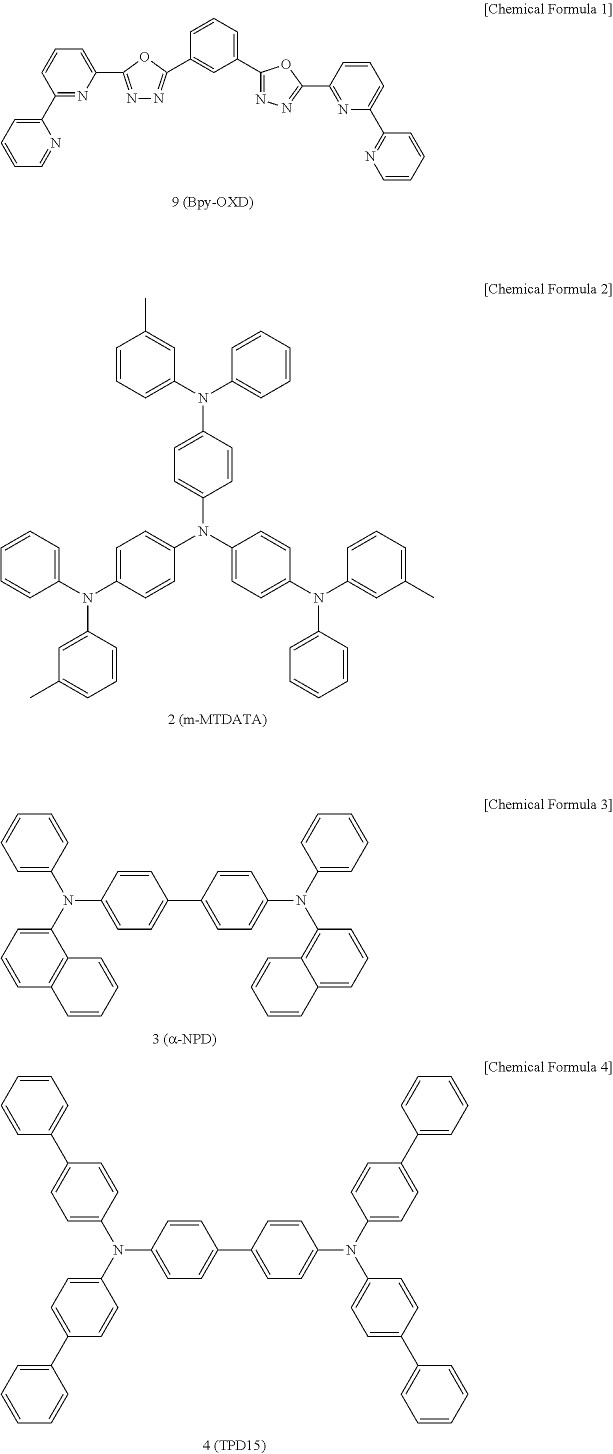 [SMILES: c1ccc(-c2cccc(-c3nnc(-c4cccc(-c5nnc(-c6cccc(-c7ccccn7)n6)o5)c4)o3)n2)nc1 ; Cc1cccc(N(c2ccccc2)c2ccc(N(c3ccc(N(c4ccccc4)c4cccc(C)c4)cc3)c3ccc(N(c4ccccc4)c4cccc(C)c4)cc3)cc2)c1 ; c1ccc(N(c2ccc(-c3ccc(N(c4ccccc4)c4cccc5ccccc45)cc3)cc2)c2cccc3ccccc23)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1]

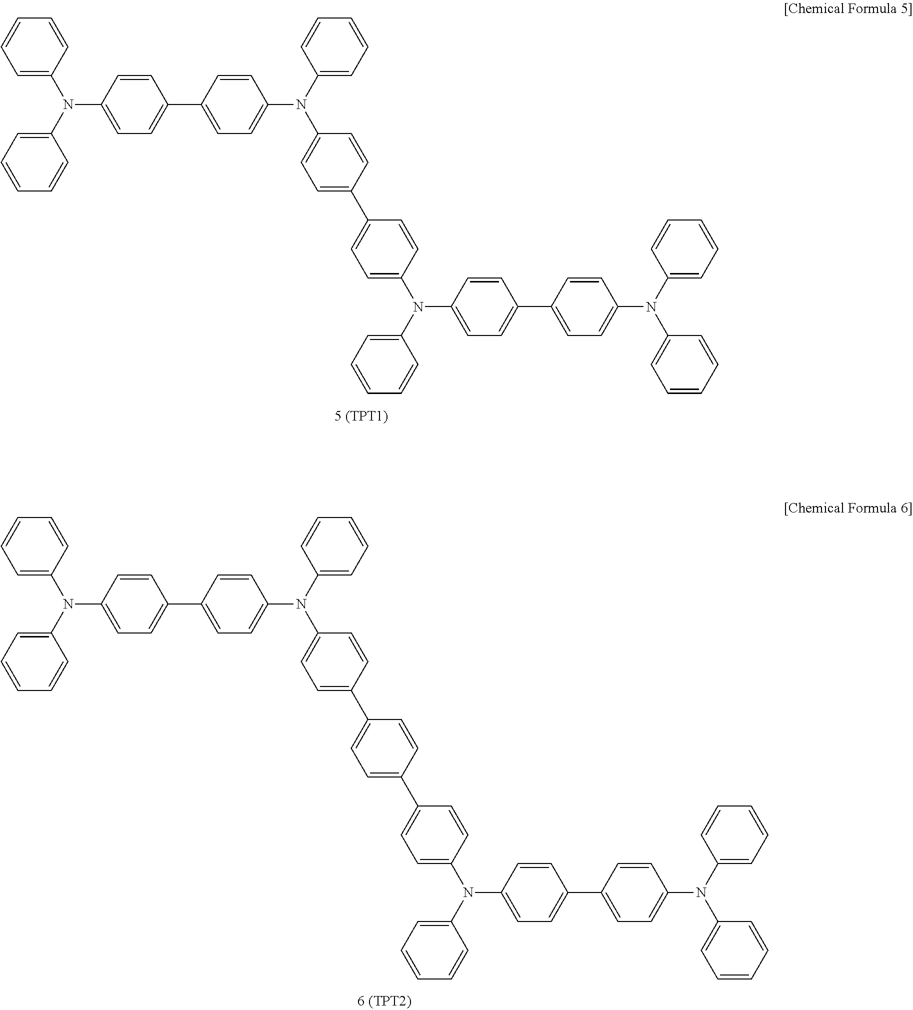 [SMILES: c1ccc(N(c2ccccc2)c2ccc(-c3ccc(N(c4ccccc4)c4ccc(-c5ccc(N(c6ccccc6)c6ccc(-c7ccc(N(c8ccccc8)c8ccccc8)cc7)cc6)cc5)cc4)cc3)cc2)cc1 ; c1ccc(N(c2ccccc2)c2ccc(-c3ccc(N(c4ccccc4)c4ccc(-c5ccc(-c6ccc(N(c7ccccc7)c7ccc(-c8ccc(N(c9ccccc9)c9ccccc9)cc8)cc7)cc6)cc5)cc4)cc3)cc2)cc1]

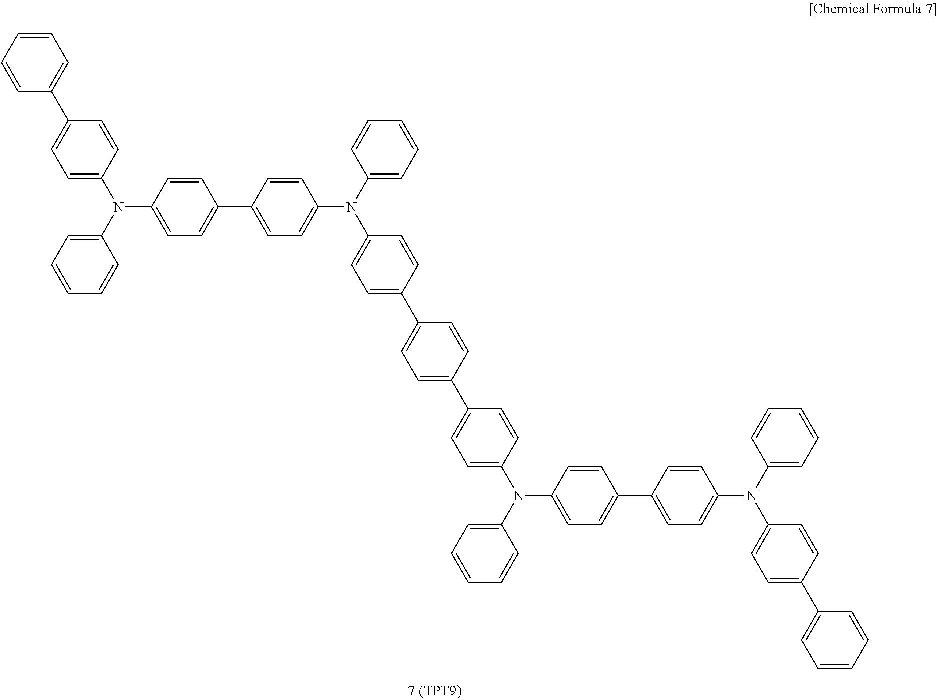 [SMILES: c1ccc(-c2ccc(N(c3ccccc3)c3ccc(-c4ccc(N(c5ccccc5)c5ccc(-c6ccc(-c7ccc(N(c8ccccc8)c8ccc(-c9ccc(N(c%10ccccc%10)c%10ccc(-c%11ccccc%11)cc%10)cc9)cc8)cc7)cc6)cc5)cc4)cc3)cc2)cc1]

11. The polarizing plate as claimed in claim 8, wherein the optical compensation layer is a C-plate.

12. The polarizing plate as claimed in claim 8, further comprising a phase delay layer provided between the polarizing layer and the optical compensation layer.

13. The polarizing plate as claimed in claim 12, wherein the phase delay layer includes a ¼ wavelength plate.

14. The polarizing plate as claimed in claim 13, wherein the phase delay layer includes a ½ wavelength plate.

15. A method of manufacturing a polarizing plate, the method comprising:
providing a polarizing film; and
depositing a substituted or non-substituted conjugated aromatic compound on the polarizing film to form an optical compensation member.

16. The method as claimed in claim 15, wherein the conjugated aromatic compound is an arylamine derivative.

17. The method as claimed in claim 16, wherein the arylamine derivative includes at least one selected from compounds represented by the following chemical formulas 1 to 7:

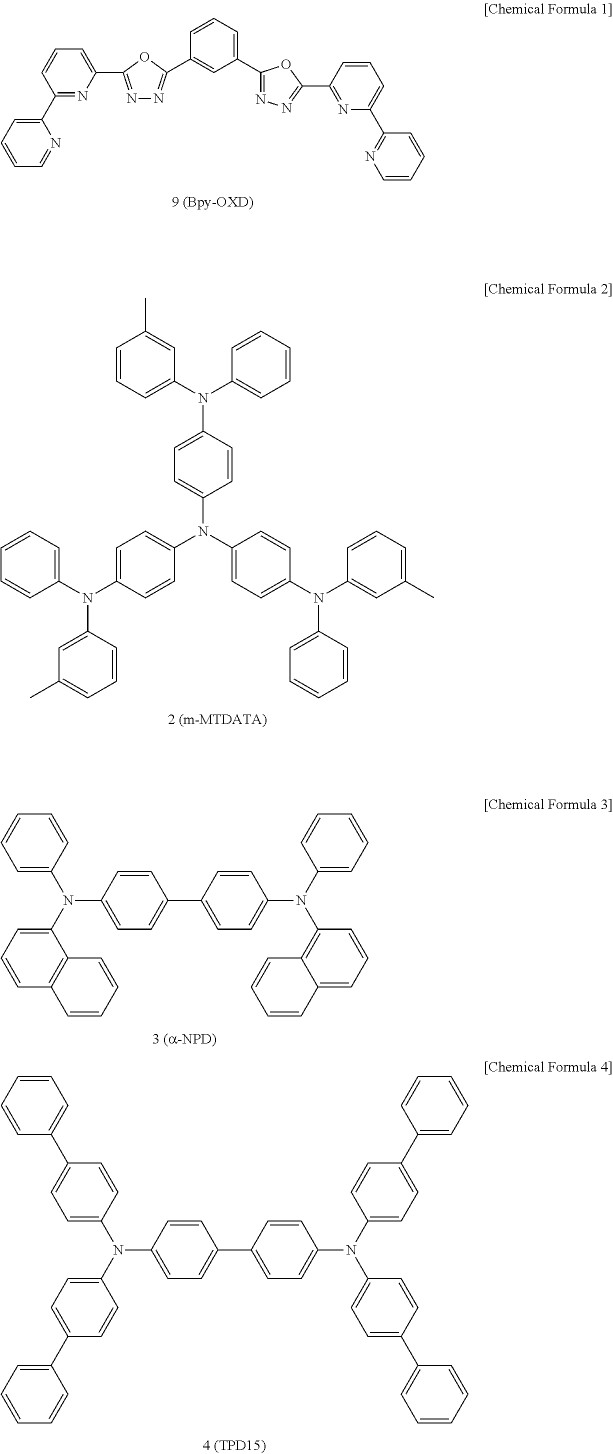 [SMILES: c1ccc(-c2cccc(-c3nnc(-c4cccc(-c5nnc(-c6cccc(-c7ccccn7)n6)o5)c4)o3)n2)nc1 ; Cc1cccc(N(c2ccccc2)c2ccc(N(c3ccc(N(c4ccccc4)c4cccc(C)c4)cc3)c3ccc(N(c4ccccc4)c4cccc(C)c4)cc3)cc2)c1 ; c1ccc(N(c2ccc(-c3ccc(N(c4ccccc4)c4cccc5ccccc45)cc3)cc2)c2cccc3ccccc23)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1]

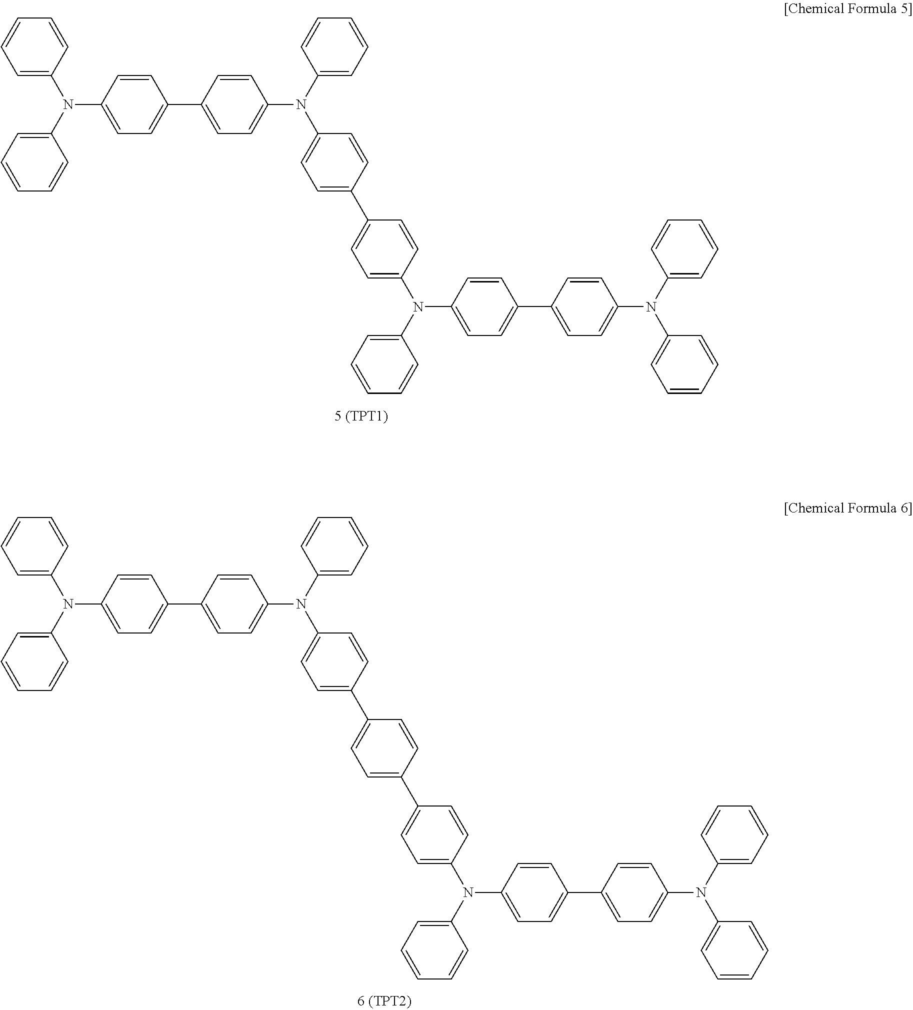 [SMILES: c1ccc(N(c2ccccc2)c2ccc(-c3ccc(N(c4ccccc4)c4ccc(-c5ccc(N(c6ccccc6)c6ccc(-c7ccc(N(c8ccccc8)c8ccccc8)cc7)cc6)cc5)cc4)cc3)cc2)cc1 ; c1ccc(N(c2ccccc2)c2ccc(-c3ccc(N(c4ccccc4)c4ccc(-c5ccc(-c6ccc(N(c7ccccc7)c7ccc(-c8ccc(N(c9ccccc9)c9ccccc9)cc8)cc7)cc6)cc5)cc4)cc3)cc2)cc1]

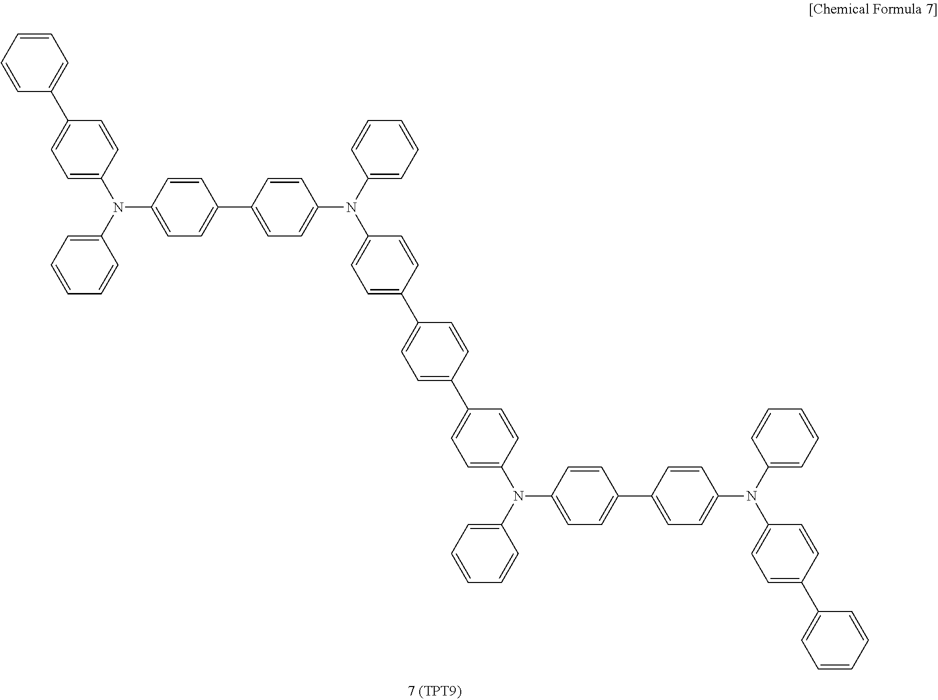 [SMILES: c1ccc(-c2ccc(N(c3ccccc3)c3ccc(-c4ccc(N(c5ccccc5)c5ccc(-c6ccc(-c7ccc(N(c8ccccc8)c8ccc(-c9ccc(N(c%10ccccc%10)c%10ccc(-c%11ccccc%11)cc%10)cc9)cc8)cc7)cc6)cc5)cc4)cc3)cc2)cc1]

18. The method as claimed in claim 15, wherein the optical compensation member is a C-plate.
